(19) United States
(12) Patent Application Publication
(10) Pub. No.: US 2003/0186519 A1
(43) Pub. Date: Oct. 2, 2003

(54) Dopant diffusion and activation control with athermal annealing

(76) Inventors: Daniel F. Downey, Gloucester, MA (US); Edwin A. Arevalo, Waltham, MA (US)

Correspondence Address: Gary L. Loser, Varian Semiconductor, Equipment Associates, Inc., 35 Dory Road, Gloucester, MA, 01930, US

(21) Appl. No.: 10/115,211

(22) Filed: Apr. 1, 2002

(51) Int. Cl. H01L 21/04; H01L 21/425

(52) U.S. Cl. 438/530; 438/528

(57) ABSTRACT

A method for forming a junction in a semiconductor by implanting a dopant and an ionic species in the semiconductor, and subjecting the semiconductor to athermal annealing. The athermal annealing, e.g., Electromagnetic Induction Heating (EMIH), can be performed using a microwave and/or RF frequency source. The dopant and the ionic species implantation can be performed simultaneously, the dopant implantation can precede the ionic species implantation, and the ionic species implantation can precede the dopant implantation. The implantation can occur using beam-line implantation or Plasma Doping (PLAD), and techniques such as preamorphized implantation (PAI) can optionally be used. A rapid thermal annealing (RTA) or low temperature rapid thermal annealing (LTRTA) process can also be applied to the semiconductor after implantation. The method can include controlling the oxygen content during the athermal (e.g., EMIH) annealing and/or other annealing (RTA and/or LTRTA) process.

### BACKGROUND

(1) Field

The disclosed methods and systems relate generally to dopant diffusion and activation control, and more particularly to dopant diffusion and activation control with electromagnetic induction heating.

(2) Description of Relevant Art

Conventional ion implantation systems include ionizing a dopant material such as boron, accelerating the ions to form an ion beam having a given energy level, and directing the ion beam energy at a semiconductor surface or wafer to introduce the dopant material to the semiconductor and alter the conductivity properties of the semiconductor. Once the ions are embedded into the crystalline lattice of the semiconductor, the ions can be activated using a process known as rapid thermal annealing (RTA) or rapid thermal process (RTP). During RTA, the semiconductor can be introduced to a furnace to heat the semiconductor at a prescribed temperature and for a prescribed time. RTA can also cure defects in the crystalline structure that can be caused by the ion implantation.

The processes of ion implantation and RTP contribute to the depth of the implanted region, known as the junction depth. The junction depth from ion implantation is based on the energy of the ions implanted into the semiconductor and the atomic or molecular weight of implanted ions. Shallow implanted regions can be formed using low-energy ion beams, and preferably, with an ion implant have a heavier atomic or molecular weight rather than a lighter weight. Unfortunately, traditional methods of RTA include raising the temperature of the silicon to ranges nearing 1100-1200 degrees Celsius, which can approach the melting temperature of the silicon. Accordingly, RTA can further increase the implanted junction depth as high temperatures of the RTA process cause further diffusion of the implanted region.

The increase in junction depth can be particularly troublesome when considered with respect to a continuing and expanding demand for smaller devices, and hence shallower junction depths. The methods and systems that combine ion implantation solely with traditional RTA may not satisfy the demand for shallower junctions.

### SUMMARY

The disclosed methods and systems include methods and systems for forming a junction in a semiconductor implanting a dopant and an ionic species in the semiconductor, and thereafter subjecting the semiconductor to an oscillating magnetic field. The oscillating magnetic field can be produced by a microwave and/or radio frequency (RF) source, for example, or any other source that provides a time-varying electromagnetic field. RF and microwave can be understood herein as two examples of a more general methodology that can be referred to herein as athermal annealing and electromagnetic induction heating (EMIH). Additionally and optionally, after the dopant and ionic species are implanted in the semiconductor, the semiconductor can be subjected to a thermal annealing process that can include Rapid Thermal Annealing (RTA) and/or a low temperature rapid thermal annealing (LTRTA).

The dopant and ionic species can be implanted simultaneously, and/or the dopant and ionic species can be implanted separately, where the order of dopant and ionic species implantation can differ based on the application. The implantation process can include beam-line implantation, plasma doping (PLAD), or another implantation method. The implantation method can also utilize preamorphized implantation (PAI). For example, in a simultaneous doping scenario, at least one of ions and molecules based on the dopant and the ionic species can be accelerated to form an ion beam and the ion beam can be directed at the semiconductor to implant the at least one of ions and molecules in the semiconductor.

In another example, a source of at least one of ions and molecules based on the dopant and the ionic species can be provided, and Plasma Doping (PLAD) can be performed to implant the at least one of ions and molecules in the semiconductor.

In some embodiments, the oxygen content can be controlled during the athermal annealing that includes electromagnetic induction heating (EMIH). In an example, the oxygen can be controlled between approximately 30 parts per million and approximately 1000 parts per million during the athermal annealing. Oxygen control can also be performed during a RTA or LTRTA process.

In one embodiment, the dopant can include a p-type dopant, and the ionic species can include a halogen. For example, the dopant can include Boron (B⁺) and the ionic species can include Fluorine (F⁻). In other embodiments, the dopant can include a n-type dopant.

Other objects and advantages will become apparent hereinafter in view of the specification and drawings.

### BRIEF DESCRIPTION OF THE DRAWINGS

FIG. 1 is one embodiment of a system and method for performing Electromagnetic Induction Heating (EMIH) annealing using microwave frequencies;

FIG. 2A is a TM011 magnetic field pattern;

FIG. 2B is a TM111 magnetic field pattern;

FIG. 3 is one embodiment of a radio frequency system and method for performing EMIH annealing;

FIG. 4 displays a relationship between power absorption and conductivity;

FIG. 5 displays a relationship between conductivity and temperature for various dopant levels;

FIG. 6 includes a SEMATECH barrier curve for evaluating improvements in anneal and doping technology;

FIG. 7 provides a SIMS profile for as-implanted and microwave spike annealed plasma doped (PLAD) samples;

FIG. 8 is a graph of BF₂ implant concentration versus junction depth using an implant energy of 500 eV and an implant dosage of 1e15 ions per square centimeter;

FIG. 9 is a plot of BF₂ implant concentration versus junction depth using an implant energy of 1.1 keV and an implant dosage of 1e15 ions per square centimeter;

FIG. 10 is a plot of BF₂ implant concentration versus junction depth using an implant energy of 2.2 keV and an implant dosage of 1e15 ions per square centimeter;

FIG. 11 is a plot of BF₂ implant concentration versus junction depth using an implant energy of 4.5 keV and an implant dosage of 1e15 ions per square centimeter;

FIG. 12 is a plot of BF₃ implant concentration versus junction depth for a Plasma Doping system using a voltage of 200V and a dosage of 5e15 ions per square centimeter;

FIG. 13 is a plot of BF₃ implant concentration versus junction depth for a Plasma Doping system using a voltage of 800V and a dosage of 1e15 ions per square centimeter; and,

FIG. 14 includes plots of ion implant concentration versus junction depth for various scenarios.

### DESCRIPTION

To provide an overall understanding, certain illustrative embodiments will now be described; however, it will be understood by one of ordinary skill in the art that the systems and methods described herein can be adapted and modified to provide systems and methods for other suitable applications and that other additions and modifications can be made without departing from the scope of the systems and methods described herein.

Unless otherwise specified, the illustrated embodiments can be understood as providing exemplary features of varying detail of certain embodiments, and therefore features, components, modules, and/or aspects of the illustrations or processes can be otherwise combined, separated, interchanged, and/or rearranged without departing from the disclosed systems or methods.

During ion implantation, the implanted regions can be damaged when the accelerated, energized dopant ions collide with the host, referred to here as an exemplary silicon surface, displacing silicon atoms from their original lattice sites. Although the dopant ions can be in high-energy non-equilibrium positions in the silicon lattice, the dopant ions are not electrically active. A rapid thermal annealing (RTA) process can provide energy to the silicon and dopant ions to allow movement of the ions to equilibrium positions, thereby also repairing the implantation damage by restoring crystallographic order. Unfortunately, the RTA process that exposes the semiconductor surface to high temperatures in the range of 1000-1200 degrees Celsius, often also causes dopant redistribution or diffusion. RTA for certain implant doses can increase junction depths to be significantly deeper than, for example, the as-implanted range.

For example, with regard to transistor devices, the consequences of a continued demand for small devices can be anticipated to include a limiting of lateral diffusion under the gate and a maintenance of high concentration of dopant material in a shallow source/drain extension region.

The disclosed methods and systems include implanting a dopant and an ionic species simultaneously, and/or consecutively where the order of implantation can vary based on application. The implantation process can include an ion implantation process such as beam-line implantation or plasma doping (PLAD), although the disclosed methods and systems are not limited to such implantation techniques. Methods including preamorphization or preamorphized implantation (PAI), among other methods, can also be used in the implantation process or method. The implantation process can be followed by an athermal annealing such as microwave and/or radio frequency (RF) annealing, although other athermal annealing methods can be used. This athermal annealing can also be referred to as electromagnetic induction heating (EMIH).

In the illustrated systems, the selected dopant is Boron (B⁺), while the ionic species is Flourine (F⁻). The disclosed processes include utilizing the ions and/or molecules based on the ionic species during implantation to produce an ionic species-rich environment during implantation and during the athermal/EMIH annealing, where the athermal annealing can follow the single or multi-stage implantation.

In one embodiment, the ionic species-rich environment can be provided via ion implantation of molecular combinations of the dopant and the ionic species. For example, ion implantation can be used to implant BF₂ to a semiconductor for forming a junction. In another example, the ionic species-rich environment can be accomplished via a Plasma-doping technique (PLAD). For example, when Boron (B⁺) is the dopant and Fluorine (F⁻) is the ionic species, PLAD can be performed using a BF₃ source. Optionally and additionally, a pre-amorphized implantation (PAI) process can be used.

Although the examples provided herein include using silicon as a semiconductor, those of ordinary skill in the art will recognize that other well-known semiconductors including the Group IV elements or compounds of Group III and Group V materials can be used in addition to, or in place of, silicon. The examples provided herein also include utilizing Boron as the selected dopant, however Aluminum, Gallium, Indium, Phosphorus, Arsenic, and Antimony, or another p-type or n-type dopant can be used in addition to or in place of Boron (B+). Further, the examples provided herein include an ionic species illustration of Fluorine, but other ionic species can be used, including but not limited to Group 17 halogens and/or halides (Fluorine, Chlorine, Bromine, Iodine, and Astatine) or other ionic species or reactive intermediates derived from Group 17, or another Group can optionally and additionally be used without departing from the scope of the disclosed processes.

EMIH can be understood as a unique application of Faraday's and Ampere's laws. As a silicon wafer is exposed to oscillating magnetic fields, electrons are induced to flow within the wafer. As the electrons collide with the lattice, they release energy that heats the silicon wafer. This athermal, internal heating via EMIH can be compared to, for example, RTA that generally exposes the wafer to a furnace at a prescribed temperature and causes the silicon to be heated from the outside surface in, thereby raising a possibility of silicon melt.

Those with ordinary skill in the art recognize that for highly conducting materials such as copper, induced currents re-induce a magnetic field that partially or completely interferes with the incident electromagnetic field. Alternately, insulating materials such as quartz lack free carriers and hence preclude any flow of current, thereby allowing the incident field to penetrate the material. Semiconductors such as silicon can have properties of conductors and insulators, and thus can have a potential for significant electromagnetic field penetration that can induce substantial currents throughout the wafer volume.

In the disclosed methods and systems, electromagnetic fields can be induced by subjecting the silicon sample to electromagnetic energy having frequencies in the radio frequency (RF) and microwave ranges, although those with ordinary skill in the art will recognize that the methods and systems are not limited to these frequency ranges, and other methods of inducing electromagnetic energy can be used. The rapid, internal ohmic heating of the wafers caused by the induced currents in the silicon wafer can cause dopant activation that can be more effective than the activation that can be caused by the surface heating provided by RTA.

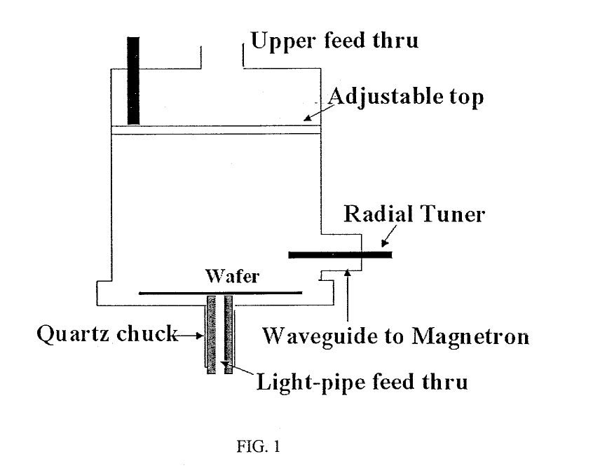

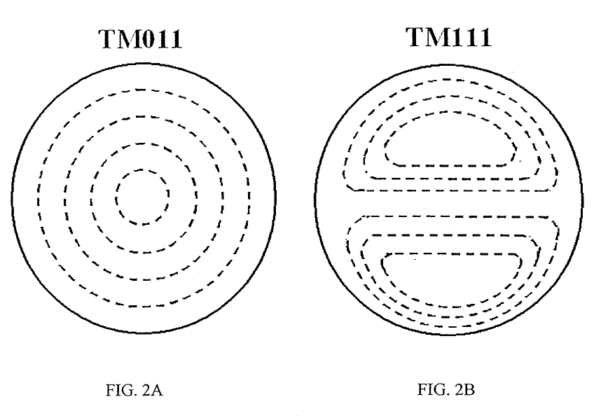

Referring now to FIG. 1, there is one embodiment of a microwave system that includes a resonant cavity having a radius of seventeen centimeters, and a height that can be adjusted between fifteen and forty-five centimeters for tuning to specific microwave modes. A magnetron source can provide a maximum three thousand watts of power at 2.45 GHz. One of ordinary skill in the art will recognize that various modes can be provided by a system according to FIG. 1, including but not limited to the well-known TM0111 and TM111 modes. FIGS. 2A and 2B provide magnetic field patterns in the FIG. 1 microwave cavity for the TM011 and TM111 modes, respectively.

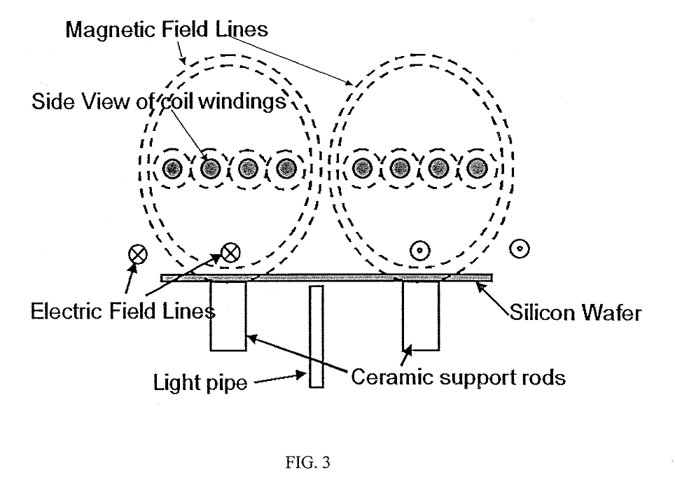

Referring to FIG. 3, there is a RF embodiment of the disclosed methods and systems that utilizes an exciting RF magnetic flux with a spiral copper antenna. A power supply matched through an L-type matching network can provide up to one-thousand Watts at a fixed 13.56 MHz frequency. In the FIG. 3 system, a silicon wafer can be positioned on a ceramic chuck two-and-a-half centimeters below the coil windings in an extreme near field of the antenna. In the illustrated system, the ceramic chuck can be heated to one-hundred fifty degrees Celsius.

Those with ordinary skill in the art will recognize that the exemplary electromagnetic induction systems of FIGS. 1 and 3 are merely illustrative and the implementation thereof is not limited to the embodiments or characteristics provided herein. Furthermore, although FIGS. 2A and 2B provide two magnetic field patterns, such patterns are provided for illustration and not limitation. Accordingly, other systems that utilize alternate methods, frequencies, apparatus, magnetic field patterns, fewer or additional components or alternatives, etc., can be used without departing from the scope of the methods and systems disclosed herein.

For the illustrated systems of FIGS. 1 and 3, temperature measurements can be provided by collecting radiated light using an optical pyrometer or light pipe. The collected radiated light can be analyzed by, for example, a Luxtron model analyzer that matches the collected light intensities to a block body radiation spectrum to produce a temperature of the silicon wafer. In some embodiments, the spectrum may be modified or scaled to provide an accurate temperature measurement based on the emissivity of silicon.

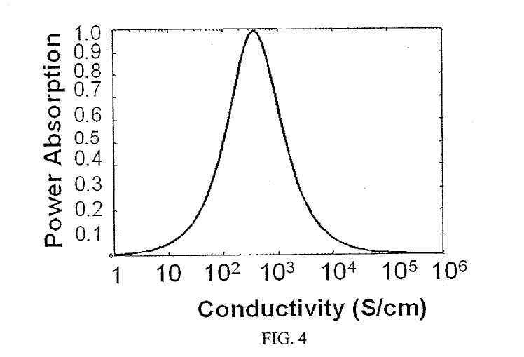

The EMIH methods and systems can allow a prediction of a magnitude of the induced currents, and hence, the temperature. As provided previously herein, a solution of Faraday's and Ampere's laws can provide a description of the induced current density and the power absorbed, where:

$${P}_{ABS} = \frac{π {a}^{2} {t}_{w}^{3} / ( {δ}^{4} σ )}{1 + {( {t}_{w} / δ )}^{4}} {H}_{0}^{2} , δ = \sqrt{2 / ωμσ} \qquad ( 1 )$$

where δ is skin depth, ω is frequency, μ is permeability, σ is conductivity, t_{w} is thickness, “a” is radius, and Hₒ is the incident magnetic field. FIG. 4 provides a plot of power absorption based on conductivity according to Equation 1. As FIG. 4 and Equation 1 indicate, the absorbed power increases with conductivity, σ, until a peak absorption is reached. Thereafter, the absorbed power decreases at the same rate of the increase and asymptotes to zero.

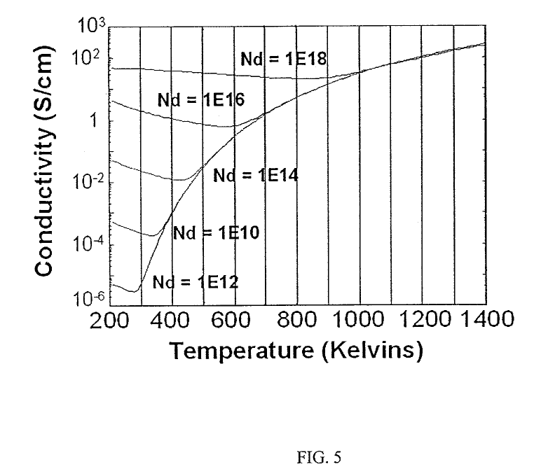

The relationship between temperature and conductivity can be instrumental to understanding the FIG. 4 relationship between power absorption and conductivity. FIG. 5 provides the relationship between conductivity and temperature for a variety of substrate doping levels. It is well-known that although conductivity can be expressed as a product of mobility and carrier density, mobility decreases with temperature due to an increased collision frequency that impedes carrier flow, while carrier density increases with temperature as the increased thermal energy moves carriers from the valence band to the conduction band. Accordingly, as FIG. 5 indicates, conductivity can decrease until the temperature exceeds approximately one-hundred degrees Celsius, during which time collisions impede carrier mobility. As the temperature further increases, the increase in intrinsic carriers can exceed the loss in mobility to allow the conductivity to monotonically increase with temperature. The largest conductivity illustrated in FIG. 5 relates to the peak power absorption level in FIG. 4, and accordingly, when viewing FIGS. 4 and 5 together as based on increasing temperature, it can be seen that for the smaller illustrated levels of doping, as temperature increases to approximately one-hundred degrees Celsius, conductivity (FIG. 5) decreases and hence power absorption (FIG. 4) is also decreasing, thereby preventing the wafer temperature from increasing. This can otherwise be known as an absorption valley. As the wafer temperature increases beyond this temperature (FIG. 5), however, conductivity increases with temperature, thereby also causing an increase in power absorption (FIG. 4) that can cause a rapid increase in temperature. At approximately five-hundred degrees Celsius, the intrinsic carrier concentration can greatly exceed the doping such that the conductivity, and hence heating, becomes independent of the substrate doping, and silicon wafers of varying dopant dosages can heat with identical characteristics.

Based on FIGS. 4 and 5, and the inference that higher frequency fields (e.g., microwave) can heat more efficiently than lower frequency fields (e.g., RF), in some embodiments, it can be necessary to pre-heat the silicon wafer to a temperature above the absorption valley. In some embodiments, for given power levels, the same wafer temperature can be achieved irrespective of whether one or more wafers are present. Accordingly, batch processing can be equally as effective.

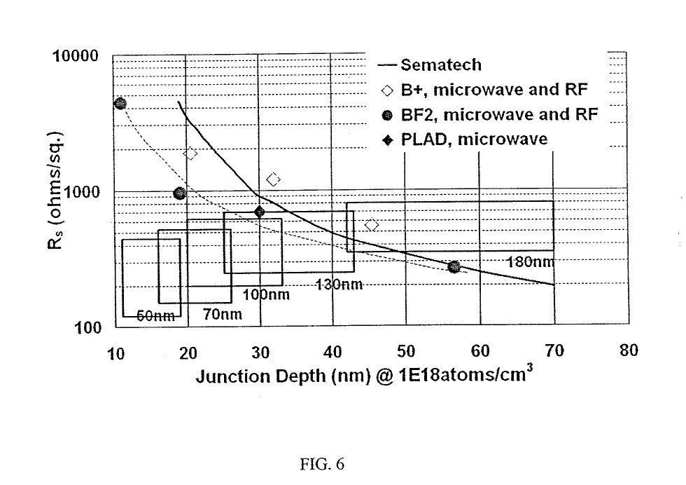

In one embodiment of the methods and systems, B⁺ and BF₂⁺ ions, at a dose of 10¹⁵/cm³, were implanted into n-type silicon wafers having resistivities between 10 and 20 ohm-cm over a range of implant energies between 250 eV and 2.2 keV. Another sample was implanted at a dose of 10¹⁵/cm² using plasma doping (PLAD) (BF₃ gas). The samples were annealed using EMIH, and specifically RF and microwave embodiments, to either 900 or 1000 degrees Celcius in an uncontrolled ambient at atmospheric pressure. FIG. 6 illustrates sheet resistances versus junction depth evaluated at 10¹⁸/cm³ from SIMS. The solid line in FIG. 6 is the present SEMATECH barrier curve for evaluating improvements in anneal and doping technology. Those of ordinary skill in the art recognize that data points below the SEMATECH curve indicate a higher percentage of activated dopants and/or a more efficient annealed dopant profile than the SEMATECH standard.

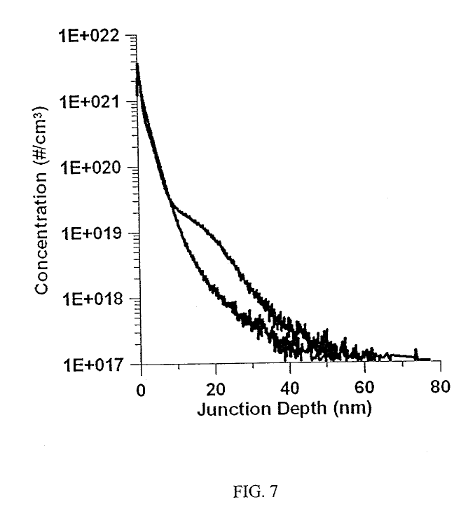

Referring now to FIG. 7, there are plots of SIMS results for the as-implanted and microwave spike annealed PLAD samples. Those with ordinary skill in the art also recognize that a more efficient profile can be obtained by a controlled ambient of oxygen (e.g. 33 to 100 ppm) to eliminate the oxygen-enhanced-diffusion effect.

In one embodiment of the methods and systems disclosed herein, sheet resistances were measured for implants of B+ at 250 eV and 500 eV, and BF2+ at 500 eV, 1.1 keV, 2.2 keV, and 4.5 keV, with implant doses of 1.0e15/cm², using EMIH annealing, and specifically, RF annealing at 13.96 MHz. In some embodiments, the RF anneal time was thirty seconds to 1000 degrees Celsius and 900 degrees Celsius, while a spike anneal was applied in other embodiments to the same temperatures. In all measured categories of ion beam energy, the thirty-second, 1000 degree temperature RF annealing provided the best sheet resistance, on the order of nearly 300 ohms/sq. to 850 ohms/sq. The remaining experiments described herein provided sheet resistances on the order of 500 ohms/sq to 7000 ohms/sq. Accordingly, although the RF annealing activates the dopant, defects remained in the lattice structure.

In another embodiment where microwave EMIH annealing was performed at 2.45 GHz, for thirty-second and spike annealing at 1000 and 900 degrees Celsius, sheet resistance measurements varied on the order of 150 ohms/sq. to 1000 ohms/sq. Once again, defects remained in the lattice structure.

By performing LTRTA (i.e., approximately 500-800 degrees Celsius) before or after EMIH annealing, defects in the lattice structure caused by the implantation can be cured without the undesirable diffusion effects caused by traditional RTA methods that necessarily provide silicon temperatures in a range between 900 degrees Celsius and 1200 degrees Celsius to activate the dopant. Accordingly, using the disclosed methods and systems that combine EMIH with LTRTA, a junction and structure having high concentration dopant activation and lattice repair with low diffusion and sheet resistance, can be achieved.

By incorporating, for example, an ionic species such as Fluorine in the implantation and annealing stages, the effects of EMIH can be further improved, irrespective of thermal annealing processes including LTRTA and RTA. As provided previously herein, the ionic species can be implanted in using one or more processes, and hence the implantation can include one or more phases. For example, beam-line implantation and/or plasma doping (PLAD) can be utilized. Additionally, in some embodiments, preamorphization (PAI) can be performed. Ions and/or molecules (e.g., BF₂) formed by the selected dopant (B⁺) and the ionic species (F⁻) can be used in the selected implantation process. For example, in an embodiment including PLAD, a BF₃ source can be used that includes the selected dopant (B⁺) and the ionic species (F⁻). Those with ordinary skill in the art will recognize that the weight of BF₂ exceeds that of B⁺, and hence it is expected that implanting BF₂ (e.g., beam-line and/or PLAD) can provide a shallower junction than implanting B⁺ alone.

The methods and systems also include controlling low level oxygen ambients during athermal annealing, where such oxygen control methods are described in U.S. Pat. No. 6,087,247 to Downey, the contents of which are herein incorporated by reference in their entirety. As provided in the aforementioned patent, during annealing, oxygen concentration can be controlled at or near a selected level in a range less than approximately 1000 parts per million and preferably in a range of about 30-300 parts per million. The oxygen control can be determined based on the selected dopant and/or the ionic species. As will be shown herein, the oxygen control can be based on a desired concentration versus junction depth profile. The oxygen concentration can be controlled by reducing the oxygen below a desired level by purging or vacuum pumping the chamber in which the athermal or EMIH annealing is performed, and introducing a controlled amount of oxygen. In another embodiment, the chamber can be backfilled with a gas that includes oxygen at or near the selected oxygen concentration level. Other gas control techniques can also be used to create the desired oxygen concentration in the annealing chamber.

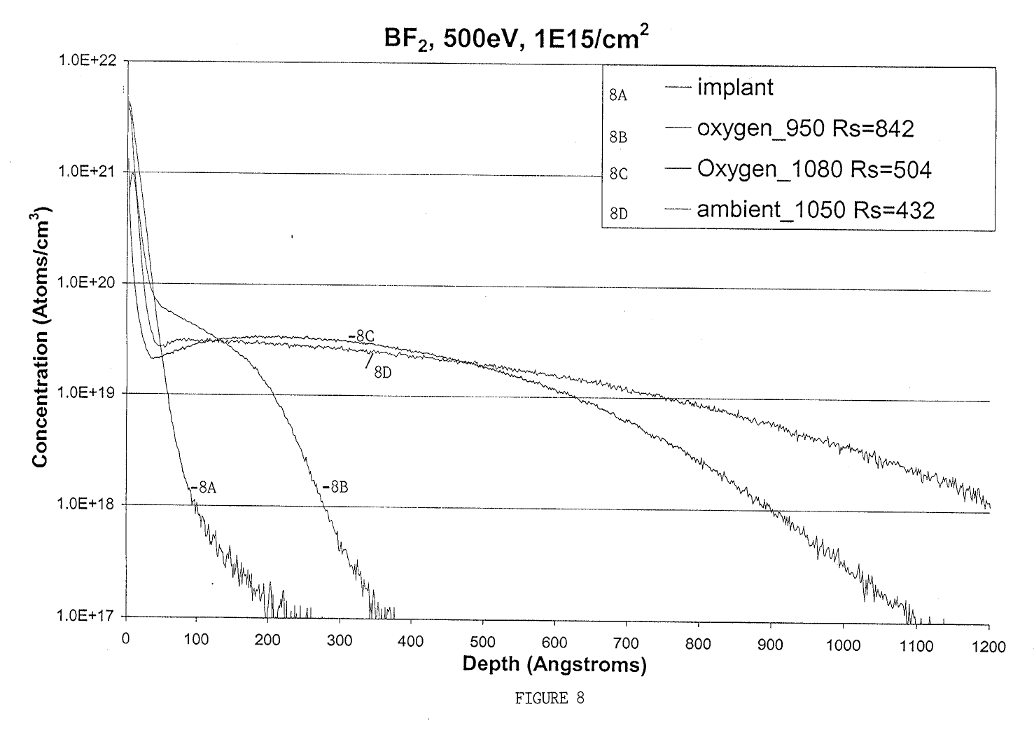

FIG. 8 provides a plot showing implant concentration versus junction depth for an ion implantation system using BF₂ at an energy of 500 eV and a concentration of 1e15 ions per square centimeter. FIG. 8 and FIGS. 9-14 similarly include an oxygen-controlled environment, when noted (O₂-control), where the oxygen-controlled environment included oxygen controlled to 100 parts per million, although such control is based on the selected dopant (B+) and can vary based on dopant selection and desired performance. Plot 8A provides the as-implanted profile, while plot 8B relates to EMIH at 950 degrees Celsius with O₂-control. Plot 8C represents EMIH at 1080 degrees Celsius with O₂-control, while Plot 8D provides data for EMIH under ambient (i.e., without O₂-control) at 1050 degrees Celsius. As the FIG. 8 plots indicate, a combination of low-temperature EMIH with O₂-control provides a shallow junction depth that most approximates the as-implanted depth, with a sheet resistance of 842 ohms. As FIG. 8 also indicates, sheet resistances for the higher temperature oxygen-controlled and ambient scenarios (504 and 432 ohms, respectively) are lower but junction depths are on the order of 1100-1200+ angstroms.

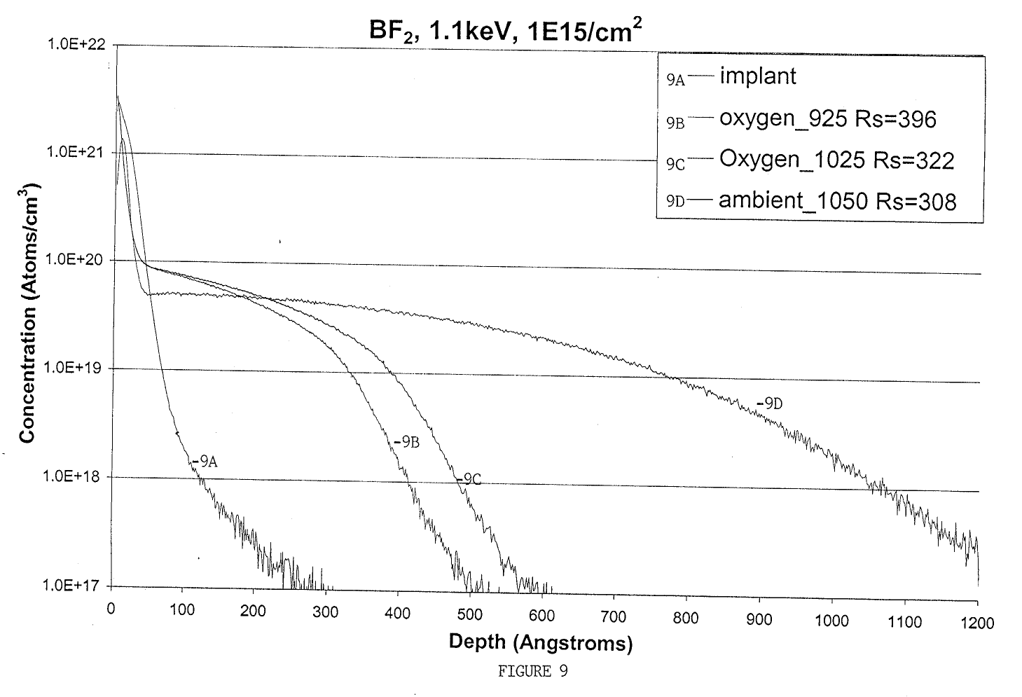

The operating conditions for FIG. 9 are similar to FIG. 8 except that the implant energy is increased in the FIG. 9 plots to 1.1 keV. As in FIG. 8, the FIG. 9 O₂-controlled EMIH scenario (9B) at 925 degrees Celsius best approximates the as-implanted profile (9A). EMIH with O₂-control and a temperature of 1025 (9C) provides a junction depth of approximately 600 angstroms, while eliminating the O₂-control and performing EMIH at 1050 degrees Celsius (9D) increases the junction depth to 1200+ angstroms.

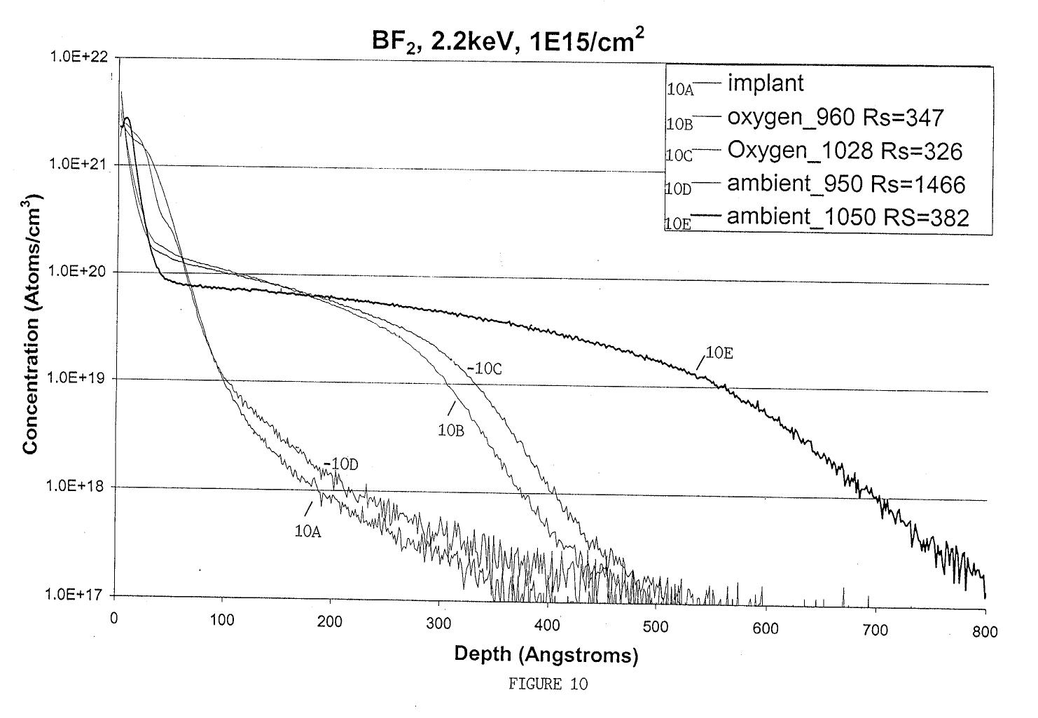

In FIG. 10, the implant energy is once again increased by a factor of two to 2.2 keV. Although EMIH performed using ambient conditions at a temperature of 950 degrees Celsius (10D) best approximates the as-implanted profile (10A), the sheet resistance is approximately 1466 ohms. In contrast, EMIH with O₂-control at 960 degrees Celsius (10B) and 1028 degrees Celsius (10C) provide junction depths of approximately 500-600 angstroms with sheet resistances of 347 ohms and 326 ohms, respectively. EMIH performed using ambient conditions at a temperature of 1050 degrees Celsius (10E) provides a junction depth of 800+ angstroms with a sheet resistance of 382 ohms.

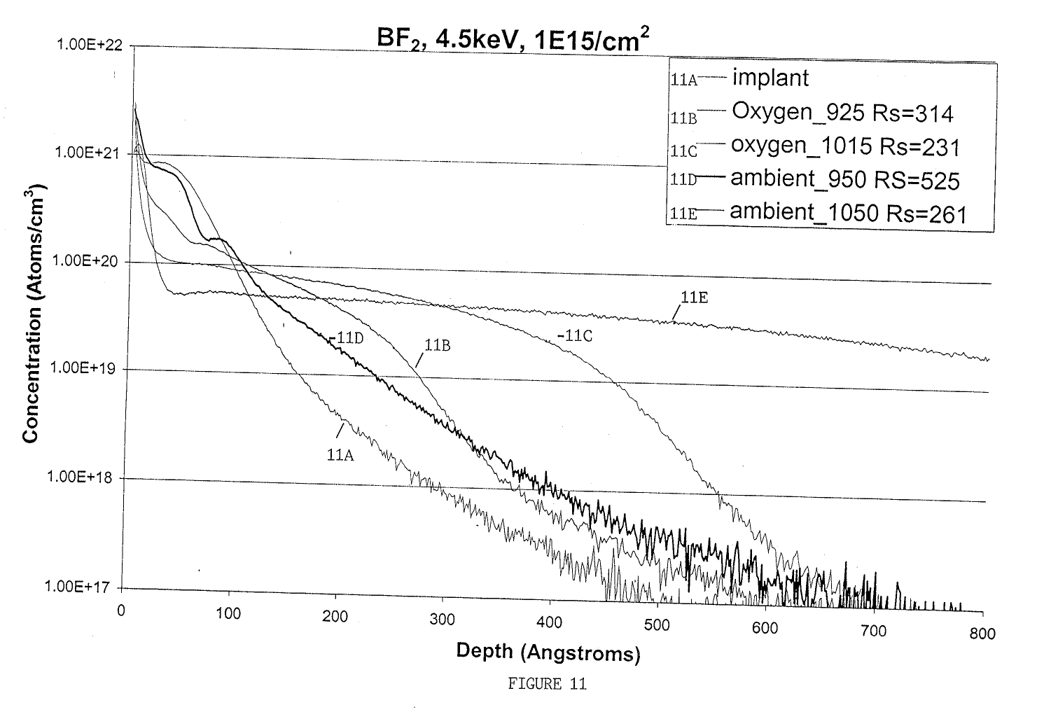

FIG. 11 provides a further increase in the implant energy as compared to FIG. 10, to 4.5 keV. The O₂-controlled EMIH performed at 925 degrees Celsius (11B) provides a junction depth of 600 angstroms with a sheet resistance of 314 ohms, as compared to the as-implanted profile (11A) that includes a junction depth of 500 angstroms. A profile with greater depth is provided by the O₂-controlled EMIH activation at 1015 degrees Celsius (11D) with a sheet resistance of 231 ohms. Under ambient conditions and EMIH at 1050 degrees Celsius (11E), a sheet resistance of 261 is indicated with junction depths exceeding 800 angstroms. The O₂-controlled EMIH plots (11B, 11C) also provide a different profile with a more constant concentration in the middle of the junction as compared to the as-implanted (11A) and ambient condition plots (11D, 11E), thereby indicating that O₂-control can affect the junction profile.

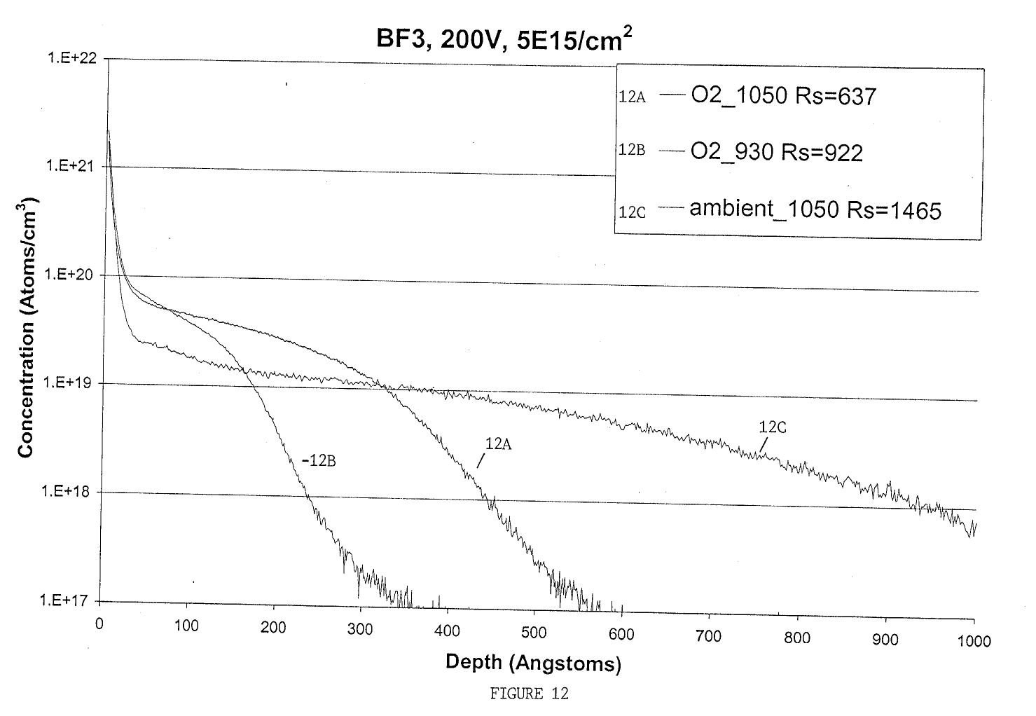

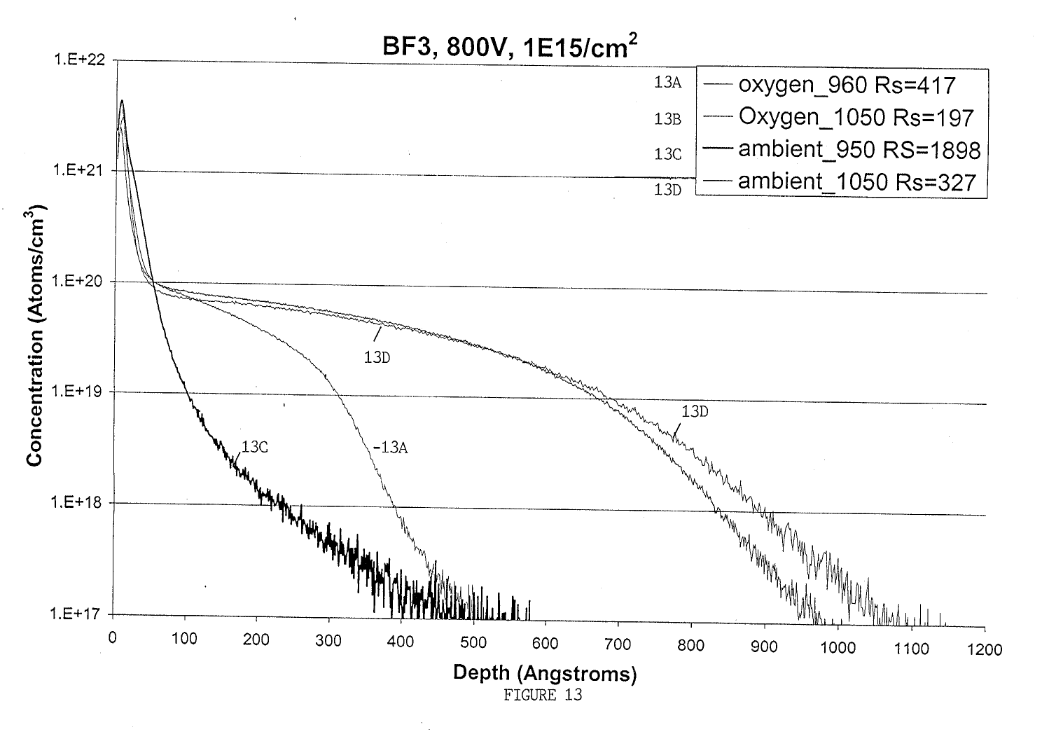

FIGS. 12 and 13 include plots of annealing using EMIH for PLAD using a BF₃ source. The FIG. 12 plots include an implantation dosage of 5e15 ions per square centimeter with a voltage of 200 volts, while FIG. 13 plots include an implantation dosage of 1e15 ions per square centimeter with a voltage of 800 volts. As FIG. 12 indicates, EMIH using O₂-control at 930 degrees Celsius (12B) provides the shallowest junction when compared to EMIH with O₂-control at 1050 degrees Celsius (12A) and ambient conditions at 1050 degrees Celsius (12C). FIG. 13 indicates that utilizing EMIH with ambient conditions at 950 degrees Celsius (13C) can provide a shallow junction with a high sheet resistance (1898 ohms) when compared to EMIH with O₂-control at 960 degrees (13A). In this latter scenario, the sheet resistance is 417 ohms with a junction depth between 500 and 600 angstroms. Performing EMIH at 1050 degrees Celsius under O₂-control (13B) provides a sheet resistance of 197 ohms with a junction depth of approximately 1000 angstroms, while eliminating O₂-control (13D) provides a sheet resistance of 327 ohms with a junction depth of approximately 1100+ angstroms.

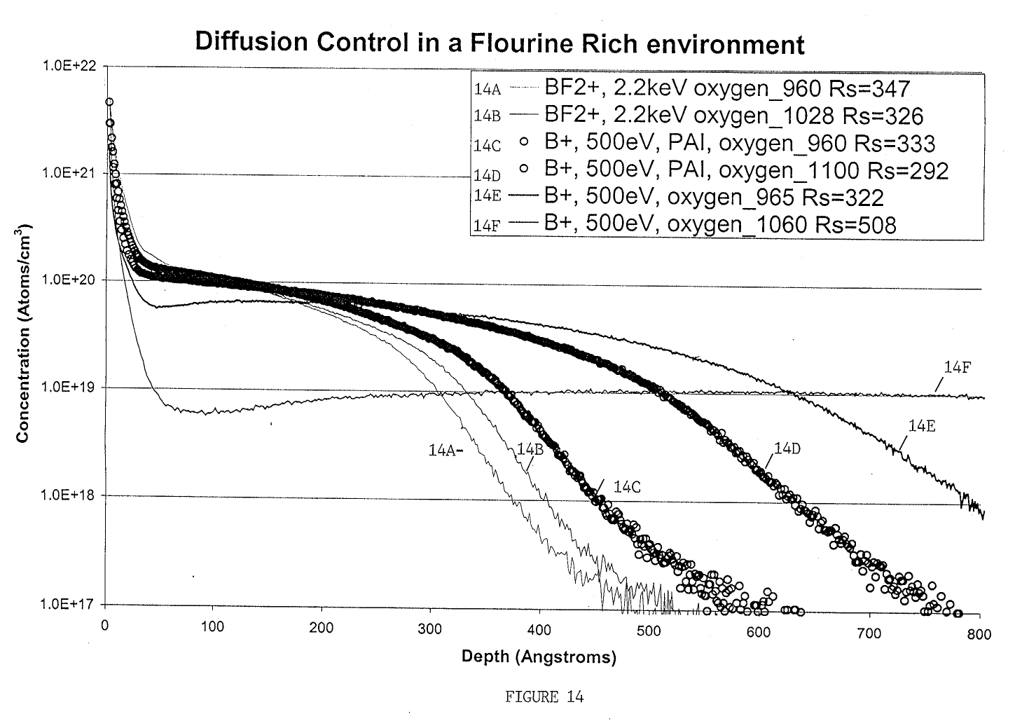

FIG. 14 presents six plots that utilize O₂-control. Plots 14A and 14B include BF₂ ion implantation using 2.2 keV at 960 and 1028 degrees Celsius, respectively, to provide sheet resistances of 347 and 326 ohms. As FIG. 14 indicates, the comparative junction depths are similar at approximately 500 angstroms. Plots 14C and 14D represent preamorphization implants (PAI) using Germanium at 30 keV and Boron at 500 eV, and EMIH at 960 and 1100 degrees Celsius, respectively. A comparison of plots 14A, 14B versus 14C and 14D indicate similar profiles for the BF2 and Germanium/Boron-PAI implants, yet the Fluorine presence in the 14A and 14B profiles provides for shallower junction depths. Plots 14E and 14F provide profiles for Boron implantation without Fluorine and without a Germanium PAI. The FIG. 14 plots indicate that although PAI using Germanium provides a shallower junction with better activation (i.e, decreased sheet resistance) than a Boron implant alone, the Fluorine (ionic species) provides additional improvement with further decreases in junction depth and equivalent activation.

What has thus been described is a method and system to achieve shallow junctions by implanting a dopant and an ionic species and thereafter performing an athermal annealing including an Electromagnetic Induction Heating (EMIH). The dopant and ionic species can be implanted simultaneously, or consecutively (i.e., separately) where the order of implantation can vary based on application. For example, the ionic species can be implanted, and then the dopant can be implanted. Alternately, the dopant can be implanted, and then the ionic species can be implanted. The EMIH can be preceded or followed by a thermal annealing that can include, for example, rapid thermal annealing (RTA) and/or low-temperature Rapid Thermal Annealing (LTRTA). The EMIH and optional thermal annealing processes can be performed in an oxygen-controlled environment utilizing relatively low oxygen levels based on the selected dopant. Preferably, the oxygen can be controlled between approximately 30 parts per million and approximately 1000 parts per million. During EMIH, the methods and systems can use, for example, RF and/or microwave frequencies to induce electromagnetic fields that can induce currents to flow within the silicon wafer, thus causing ohmic collisions between electrons and the lattice structure that heat the wafer volumetrically rather than through the surface. Such EMIH heating can activate the dopant material.

The methods and systems described herein are not limited to a particular hardware or software configuration, and may find applicability in many computing or processing environments. The methods and systems can be implemented in hardware or software, or a combination of hardware and software. The methods and systems can be implemented in one or more computer programs executing on one or more programmable computers that include a processor, a storage medium readable by the processor (including volatile and non-volatile memory and/or storage elements), one or more input devices, and one or more output devices.

Although the methods and systems have been described relative to a specific embodiment thereof, they are not so limited. Obviously many modifications and variations may become apparent in light of the above teachings. For example, as previously provided herein, although the Figures illustrated the use of Boron (B⁺) as a selected p-type dopant with a Fluorine (F⁻) as the selected ionic species, the methods and systems can be applied to other p-type and n-type dopants, as well as other ionic species. In accordance with the Boron examples, the illustrated embodiments include an oxygen-controlled annealing chamber at a desired oxygen level of approximately 100 parts per million, although those with ordinary skill in the art will recognize that the controlled oxygen amount can vary based on the dopant, and can range between 1 and 1000 parts per million, for example. Although LTRTA was illustrated as approximately 500-800 degrees Celsius, where the LTRTA can be performed using a furnace, LTRTA can be understood to include an exposure to temperatures less than approximately 800 degrees Celsius. The methods and systems disclosed include providing an oscillating magnetic field to provide an electromagnetic field and induce currents in the semiconductor, and although the illustrated methods and systems provided RF and microwave systems, any electromagnetic wave of any frequency that provides a time-varying or oscillating magnetic field can be used. For example, an EMIH embodiment can include a permanent magnet that can be moved to provide a time-varying magnetic field. Furthermore, other athermal annealing processes can be used.

Many additional changes in the details, materials, and arrangement of parts, herein described and illustrated, can be made by those skilled in the art. Accordingly, it will be understood that the following claims are not to be limited to the embodiments disclosed herein, can include practices otherwise than specifically described, and are to be interpreted as broadly as allowed under the law.

What is claimed is:

1. A method for forming a junction in a semiconductor, the method comprising:
implanting a dopant and an ionic species in the semiconductor, and thereafter,
subjecting the semiconductor to an oscillating magnetic field.

2. A method according to claim 1, further comprising,
applying a low temperature rapid thermal annealing (LTRTA) process to the semiconductor.

3. A method according to claim 2, wherein applying a LTRTA can occur at least one of before and after subjecting the semiconductor to an oscillating magnetic field.

4. A method according to claim 1, further comprising subjecting the semiconductor to a rapid thermal annealing (RTA) process after implanting the dopant and the ionic species.

5. A method according to claim 1, further comprising:
accelerating at least one of ions and molecules based on the dopant and the ionic species to form an ion beam, and,
directing the ion beam at the semiconductor to implant the at least one of ions and molecules in the semiconductor.

6. A method according to claim 1, further comprising:
performing Plasma Doping (PLAD) to implant in the semiconductor at least one of ions and molecules based on the dopant and the ionic species.

7. A method according to claim 1, wherein implanting the dopant and ionic species includes performing preamorphized implantation (PAI).

8. A method according to claim 1, wherein implanting the dopant and the ionic species in the semiconductor includes at least one of: implanting the dopant and thereafter implanting the ionic species, implanting the ionic species and thereafter implanting the dopant, and implanting the dopant and the ionic species simultaneously.

9. A method according to claim 1, wherein implanting the dopant and the ionic species includes using at least one of beam-line implantation, Plasma doping (PLAD), and preamorphized implantation (PAI).

10. A method according to claim 1, further including controlling the oxygen content based on the dopant while subjecting the semiconductor to an oscillating magnetic field.

11. A method according to claim 1, further including controlling the oxygen content to a range between approximately 30 parts per million and approximately 1000 parts per million, while subjecting the semiconductor to an oscillating magnetic field.

12. A method according to claim 1, wherein the dopant includes Boron.

13. A method according to claim 1, wherein the ionic species includes a halogen.

14. A method according to claim 1, wherein:
the dopant includes Boron, and,
the ionic species includes a halogen.

15. A method according to claim 1, wherein the dopant includes at least one of an n-type dopant and a p-type dopant.

16. A method according to claim 1, wherein subjecting includes subjecting to a time-varying electromagnetic field.

17. A method according to claim 1, wherein subjecting includes subjecting to a microwave frequency.

18. A method according to claim 1, wherein subjecting includes subjecting to a radio frequency (RF).

19. A method according to claim 2, wherein applying a LTRTA includes exposing the semiconductor to a temperature less than approximately 800 degrees Celsius.

20. A method according to claim 2, wherein applying a LTRTA includes exposing the semiconductor to a furnace having a temperature greater than approximately 500 degrees Celsius, and less than approximately 800 degrees Celsius.

21. A method for implanting a dopant in a semiconductor, the method comprising:
implanting a dopant and an ionic species in the semiconductor, and thereafter,
subjecting the semiconductor to electromagnetic induction heating (EMIH).

22. A method according to claim 21, further including:
applying a low-temperature rapid thermal anneal (LTRTA) after implanting the dopant and the ionic species.

23. A method according to claim 21, further including:
applying a rapid thermal annealing process after implanting the dopant and the ionic species.

24. A method according to claim 21, wherein the selected dopant is at least one of an n-type dopant and a p-type dopant.

25. A method according to claim 21, wherein subjecting the semiconductor to EMIH includes subjecting the dopant to an oscillating magnetic field.

26. A method according to claim 21, wherein subjecting the semiconductor to EMIH includes includes subjecting the dopant to a time-varying electromagnetic field.

27. A method according to claim 21, wherein subjecting the semiconductor to EMIH includes subject to at least one of a Radio Frequency (RF) and a microwave frequency.

28. A method according to claim 22, wherein applying a LTRTA includes exposing the semiconductor to a temperature less than approximately 800 degrees Celsius.

29. A method according to claim 21, further including controlling the oxygen while subjecting the semiconductor to EMIH.

30. A method according to claim 21, further including controlling the oxygen between a range of approximately 30 parts per million and approximately 1000 parts per million, while subjecting the semiconductor to EMIH.

31. A method according to claim 21, wherein the dopant includes Boron and the ionic species includes a halogen.

32. A method according to claim 21, wherein implanting the dopant and the ionic species includes using at least one of beam-line implantation, Plasma doping (PLAD), and preamorphized implantation (PAI).

33. A method according to claim 21, wherein implanting the dopant and the ionic species in the semiconductor includes at least one of: implanting the dopant and thereafter implanting the ionic species, implanting the ionic species and thereafter implanting the dopant, and implanting the dopant and the ionic species simultaneously.

34. A method for implanting a dopant in a semiconductor, the method comprising:
implanting a dopant and an ionic species in the semiconductor, and thereafter,
subjecting the semiconductor to athermal annealing.

35. A method according to claim 34, further including subjecting the semiconductor to thermal annealing.

36. A method according to claim 35, wherein thermal annealing includes at least one of rapid thermal annealing (RTA) and low temperature rapid thermal annealing (LTRTA).

37. A method according to claim 34, further including controlling the oxygen between approximately 30 parts per million and approximately 1000 parts per million while subjecting the semiconductor to athermal annealing.

38. A method according to claim 34, wherein implanting the dopant and the ionic species includes using at least one of ion implantation, Plasma doping (PLAD), and preamorphized implantation (PAI).

39. A method according to claim 34, wherein implanting the dopant and the ionic species in the semiconductor includes at least one of: implanting the dopant and thereafter implanting the ionic species, implanting the ionic species and thereafter implanting the dopant, and implanting the dopant and the ionic species simultaneously.

40. A method according to claim 34, wherein subjecting the semiconductor to athermal annealing includes subjecting the semiconductor to at least one of a Radio Frequency (RF) and a microwave frequency.

41. A method according to claim 34, wherein the semiconductor includes at least one Group IV elements and compounds of Group III and Group V materials.

42. A method for implanting a dopant in a semiconductor, the method comprising:
implanting a dopant and an ionic species in the semiconductor, and thereafter,
subjecting the semiconductor to an electromagnetic wave.

43. A method according to claim 42, wherein the electromagnetic wave includes at least one of a radio frequency (RF) and a microwave frequency.

44. A method according to claim 42, further including controlling the oxygen between a range of approximately 30 parts per million and approximately 1000 parts per million, while subjecting the semiconductor to an electromagnetic wave.

45. A method according to claim 42, wherein the dopant includes Boron and the ionic species includes a halogen.

46. A method according to claim 42, wherein implanting the dopant and the ionic species includes using at least one of beam-line implantation, Plasma doping (PLAD), and preamorphized implantation (PAI).

47. A method according to claim 42, wherein implanting the dopant and the ionic species in the semiconductor includes at least one of: implanting the dopant and thereafter implanting the ionic species, implanting the ionic species and thereafter implanting the dopant, and implanting the dopant and the ionic species simultaneously.

48. A method according to claim 42, further including, after implanting, subjecting the semiconductor to at least one of a rapid thermal annealing (RTA) and a low temperature rapid thermal annealing (LTRTA).

49. A method according to claim 48, including controlling the oxygen between a range of approximately 30 parts per million and approximately 1000 parts per million, while subjecting the semiconductor to at least one of a rapid thermal annealing (RTA) and a low temperature rapid thermal annealing (LTRTA).
